(19) United States
(12) Patent Application Publication
(10) Pub. No.: US 2024/0429704 A1
(43) Pub. Date: Dec. 26, 2024

(54) ELECTROSTATIC DISCHARGE (ESD) PROTECTION CIRCUITRY FOR REDUCED INTERFERENCE FROM BULK CURRENT INJECTION (BCI) NOISE

(71) Applicant: Microchip Technology Incorporated, Chandler, AZ (US)

(72) Inventors: Naveen Cannankurichi, Hyderabad (IN); Jebas Paul Daniel T, Tirunelveli (IN)

(21) Appl. No.: 18/750,206

(22) Filed: Jun. 21, 2024

(30) Foreign Application Priority Data
Jun. 23, 2023 (IN) 202341042280

(51) Int. Cl. H02H 9/04

(52) U.S. Cl. CPC H02H 9/04

(57) ABSTRACT

An apparatus comprises an electrostatic discharge (ESD) protection circuitry including a first diode having a cathode coupled to a first signal input and an anode coupled to a signal ground input, a second diode having a cathode coupled to a second signal input and an anode coupled to the signal ground input, and a third diode having a cathode coupled to the signal ground input and an anode coupled to a substrate ground. In one or more examples, the apparatus comprises an analog front-end including a first analog front-end circuitry coupled to the first signal input and the signal ground input, and a second analog front-end circuitry coupled to the second signal input and the signal ground input.

### CROSS-REFERENCE TO RELATED APPLICATION

This application claims the benefit of the filing date of Republic of India Provisional Patent Application Serial No. 202341042280, filed Jun. 23, 2023, for “Electrostatic Discharge (ESD) Structure for Inductive Position Sensor Circuitry,” the disclosure of which is hereby incorporated herein in its entirety by this reference.

### TECHNICAL FIELD

This disclosure relates generally to electrostatic discharge (ESD) protection circuitry or structures. More specifically, some examples relate to ESD protection circuitry for reduced interference from bulk current injection (BCI) noise in inductive position sensors, without limitation. Additionally, apparatuses and systems are disclosed.

### BACKGROUND

If a coil of wire is placed in a changing magnetic field, a voltage will be induced at ends of the coil of wire. In a predictably changing magnetic field, the induced voltage will be predictable (based on factors including the area of the coil affected by the magnetic field and the degree of change of the magnetic field). It is possible to disturb a predictably changing magnetic field and measure a resulting change in the voltage induced in the coil of wire. Further, it is possible to create a sensor that measures a position of a disturber (e.g., a target) of a predictably changing magnetic field based on a change in a voltage induced in a coil of wire. However, such a sensor may be subject to external noise which interferes with measurements of the position of the target.

### BRIEF DESCRIPTION OF THE DRAWINGS

While this disclosure concludes with claims particularly pointing out and distinctly claiming specific examples, various features and advantages of examples within the scope of this disclosure may be more readily ascertained from the following description when read in conjunction with the accompanying drawings, in which:

FIG. 1 is a schematic diagram of an inductive position sensor, according to one or more examples of the disclosure;

FIG. 2 is a schematic diagram of the inductive position sensor of FIG. 1 including an integrated circuit (IC), according to one or more examples;

FIG. 3 is a schematic diagram of electronic circuitry of the IC of FIG. 2, according to one or more examples;

FIG. 4 is a schematic diagram of the IC including electrostatic discharge (ESD) protection circuitry, according to one or more examples;

FIG. 5 is another schematic diagram of the IC including the ESD protection circuitry of FIG. 4, according to one or more examples;

FIG. 6A is a schematic diagram of a system including the inductive position sensor and a power source for supply power to the inductive position sensor in a normal operation, according to one or more examples;

FIG. 6B is a schematic diagram of the system of FIG. 6A in a ground off condition, according to one or more examples;

FIG. 7 is a depiction of a bulk current injection (BCI) test setup for testing a device under test, which may be the inductive position sensor of FIGS. 2, 3, 4, and 5;

FIG. 8A is a circuit diagram to represent differential (normal) mode noise to be measured in a differential mode BCI (DBCI) testing method;

FIG. 8B is a circuit diagram to represent common mode noise to be measured in a common mode BCI (CBCI) testing method;

FIG. 9 is a table depicting angle outputs versus injection voltage magnitudes for an inductive position sensor or IC including an ESD protection circuitry, according to one or more examples;

FIG. 10 is a graph depicting noise immunity level versus frequency for measured DBCI of an inductive position sensor or IC including an ESD protection circuitry, according to one or more examples;

FIG. 11 is a graph depicting duty cycle versus frequency for measured CBCI of an inductive position sensor or IC including an ESD protection circuitry, according to one or more examples;

FIG. 12 is a graph of transient voltage over time for depicting ground off sensitivity for an inductive position sensor or IC including an ESD protection circuitry, according to one or more examples;

FIG. 13 is a schematic diagram of an IC including an ESD protection circuitry that is known to the inventors of the disclosure;

FIG. 14 is another schematic diagram of the IC including the ESD protection circuitry of FIG. 13;

FIG. 15 is table for depicting angle outputs versus injection voltage magnitudes for the inductive position sensor or IC including the ESD protection circuitry, according to one or more examples, and including angle outputs for the inductive position sensor or IC without the new ESD protection circuitry;

FIG. 16 is a graph depicting noise immunity level versus frequency for measured DBCI of an inductive position sensor or IC without the new ESD protection circuitry;

FIG. 17 is a graph depicting duty cycle versus frequency for measured CBCI of an inductive position sensor or IC without the new ESD protection circuitry; and

FIG. 18 is a graph of transient voltage over time for depicting ground off sensitivity for an inductive position sensor or IC without the new ESD protection circuitry.

### DETAILED DESCRIPTION

In the following detailed description, reference is made to the accompanying drawings, which form a part hereof, and in which are shown, by way of illustration, specific examples of examples in which the present disclosure may be practiced. These examples are described in sufficient detail to enable a person of ordinary skill in the art to practice the present disclosure. However, other examples may be utilized, and structural, material, and process changes may be made without departing from the scope of the disclosure.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, the similarity in numbering does not mean that the structures or components are necessarily identical in size, composition, configuration, or any other property.

The following description may include examples to help enable one of ordinary skill in the art to practice the disclosed examples. The use of the terms “exemplary,” “by example,” and “for example,” means that the related description is explanatory, and though the scope of the disclosure is intended to encompass the examples and legal equivalents, the use of such terms is not intended to limit the scope of an example of this disclosure to the specified components, steps, features, functions, or the like.

It will be readily understood that the components of the examples as generally described herein and illustrated in the drawing could be arranged and designed in a wide variety of different configurations. Thus, the following description of various examples is not intended to limit the scope of the present disclosure, but is merely representative of various examples. While the various aspects of the examples may be presented in drawings, the drawings are not necessarily drawn to scale unless specifically indicated.

Furthermore, specific implementations shown and described are only examples and should not be construed as the only way to implement the present disclosure unless specified otherwise herein. Elements, circuits, and functions may be depicted by block diagram form in order not to obscure the present disclosure in unnecessary detail. Conversely, specific implementations shown and described are exemplary only and should not be construed as the only way to implement the present disclosure unless specified otherwise herein. Additionally, block definitions and partitioning of logic between various blocks is exemplary of a specific implementation. It will be readily apparent to one of ordinary skill in the art that the present disclosure may be practiced by numerous other partitioning solutions. For the most part, details concerning timing considerations and the like have been omitted where such details are not necessary to obtain a complete understanding of the present disclosure and are within the abilities of persons of ordinary skill in the relevant art.

Those of ordinary skill in the art would understand that information and signals may be represented using any of a variety of different technologies and techniques. For example, data, instructions, commands, information, signals, bits, and symbols that may be referenced throughout this description may be represented by voltages, currents, electromagnetic waves, magnetic fields or particles, optical fields or particles, or any combination thereof. Some drawings may illustrate signals as a single signal for clarity of presentation and description. It will be understood by a person of ordinary skill in the art that the signal may represent a bus of signals, wherein the bus may have a variety of bit widths and the present disclosure may be implemented on any number of data signals including a single data signal. A person having ordinary skill in the art would appreciate that this disclosure encompasses communication of quantum information and qubits used to represent quantum information.

The various illustrative logical blocks, modules, and circuits described in connection with the examples disclosed herein may be implemented or performed with a general purpose processor, a special purpose processor, a Digital Signal Processor (DSP), an Integrated Circuit (IC), an Application Specific Integrated Circuit (ASIC), a Field Programmable Gate Array (FPGA) or other programmable logic device, discrete gate or transistor logic, discrete hardware components, or any combination thereof designed to perform the functions described herein. A general-purpose processor (may also be referred to herein as a host processor or simply a host) may be a microprocessor, but in the alternative, the processor may be any conventional processor, controller, microcontroller, or state machine. A processor may also be implemented as a combination of computing devices, such as a combination of a DSP and a microprocessor, a plurality of microprocessors, one or more microprocessors in conjunction with a DSP core, or any other such configuration. A general-purpose computer including a processor is considered a special-purpose computer while the general-purpose computer is configured to execute computing instructions (e.g., software code) related to examples of the present disclosure.

The examples may be described in terms of a process that is depicted as a flowchart, a flow diagram, a structure diagram, or a block diagram. Although a flowchart may describe operational acts as a sequential process, many of these acts can be performed in another sequence, in parallel, or substantially concurrently. In addition, the order of the acts may be re-arranged. A process may correspond to a method, a thread, a function, a procedure, a subroutine, or a subprogram, without limitation. Furthermore, the methods disclosed herein may be implemented in hardware, software, or both. If implemented in software, the functions may be stored or transmitted as one or more instructions or code on computer-readable media. Computer-readable media includes both computer storage media and communication media including any medium that facilitates transfer of a computer program from one place to another.

An inductive position sensor may include one or more oscillator coils, a first sense coil, a second sense coil, and a target. The one or more oscillator coils, the first sense coil, and the second sense coil may be laid out as conductive traces on or in one or more layers (e.g., planes) of a substrate, such as a printed circuit board (PCB). The inductive position sensor may further include an integrated circuit (IC) including an oscillator to drive the oscillator coil and electronic circuits to receive and demodulate respective outputs of the first and second sense coils. Such an inductive position sensor may perform signal processing for determining a linear or angular position of the target relative to the one or more oscillator coils or the sense coils.

During operation, the oscillator may generate an excitation signal. The one or more oscillator coils may be excited by the excitation signal. The oscillating signal on the one or more oscillator coils may generate a changing (oscillating) magnetic field near and especially within a space encircled by the oscillator coil, although not limited thereto. The changing magnetic field generated by the one or more oscillator coils may induce a first oscillating voltage at ends of the first sense coil and a second oscillating voltage at ends of the second sense coil. The first oscillating voltage at the ends of the first sense coil may oscillate in response to the oscillation of the excitation signal and may be a first sense signal. The second oscillating voltage at the ends of the second sense signal may oscillate in response to the oscillation of the excitation signal and may be a second sense signal.

The target may be positioned relative to the one or more oscillator coils, the first sense coil, and the second sense coil. For example, the target, or a portion of the target, may be positioned above, or beneath, a portion of the one or more oscillator coils, the first sense coil, and the second sense coil, without limitation. The target may disrupt some of the changing magnetic field that passes through one or more loops of the first sense coil and the second sense coil. The location of the target, or the portion of the target, above or beneath the one or more oscillator coils, the first sense coil, and the second sense coil may affect the first sense signal and the second sense signal induced in the first sense coil and the second sense coil, respectively. For example, the target may disrupt magnetic coupling between the one or more oscillator coils and the first and second sense coils. Such disruption may affect a magnitude of the first and second sense signals induced in the first and second sense coils, respectively. For example, in response to the target, or a portion of the target, being over a loop in the first sense coil, the amplitude of the first sense signal may be less than the amplitude of the first sense signal when the target is not over the loop in the first sense coil. Further, the target may move such that a portion of the target may pass over, or under, one or more loops of one or more of the first sense coil and the second sense coil and/or over, or under, portions of the one or more oscillator coils that are proximate to loops of the first and the second sense coils. As the target moves, the first sense signal of the first sense coil and the second sense signal of the second sense coil may be amplitude modulated in response to the rotation of the target and in response to the portion of the target passing over, or under, the loops of the first and the second sense coils and/or over or under portions of the one or more oscillator coils proximate to the loops of the first and the second sense coils.

In one or more examples, the IC may generate an output signal responsive to the first sense signal and the second sense signal. The output signal may be a fraction of a rail voltage, or a digital signal, based on the first sense signal and the second sense signal. The output signal may be related to the position of the target, or the position of the portion of the target, and successive samples of the output signal may be related to a direction of movement of the target. Thus, the inductive position sensor may generate an output signal indicative of a position of a target. In one or more examples, the IC may generate a first output signal based on the first sense signal and a second output signal based on the second sense signal. The first output signal may be the first sense signal demodulated; the second output signal may be the second sense signal demodulated. Together, the two output signals may be related to the position of the target and subsequent samples of the first and second output signals may be indicative of rotation of the target. In one or more examples, the IC may generate a single output signal based on the first sense signal and the second sense signal. As a non-limiting example, the IC may generate the single output signal based on a relationship (e.g., an arctangent, without limitation) of the first sense signal and the second sense signal.

During operation, the inductive position sensor may be subject to substantial external noise which interferes with measurements of the position of the target. In an automotive environment, for example, a vehicle contains a wiring harness as a source of noise. The wiring harness typically includes an organized set of wires, terminals and connectors that run throughout a vehicle and relay information and electric power to and from different vehicle components. In such an environment, high frequency currents are injected into power lines and traverse through the PCB lines of the inductive position sensor to the input pins of the IC. As the sensor coils are formed on, or in, the PCB, stray PCB resonances may be triggered to result in high voltage amplitudes at the input pins. As a result of the external noise, position signal measurements of the inductive position sensor may be adversely affected.

Various examples of the disclosure include an electrostatic discharge (ESD) protection circuitry or structure to reduce the impact of injected noise while maintaining ESD performance. In one or more examples, the disclosure relates to an IC including the ESD protection circuitry for a non-contacting, planar inductive position sensor. The disclosed inductive position sensor, sensor IC, and/or ESD protection circuitry may be utilized in a variety of operational contexts, such as in automotive applications, without limitation.

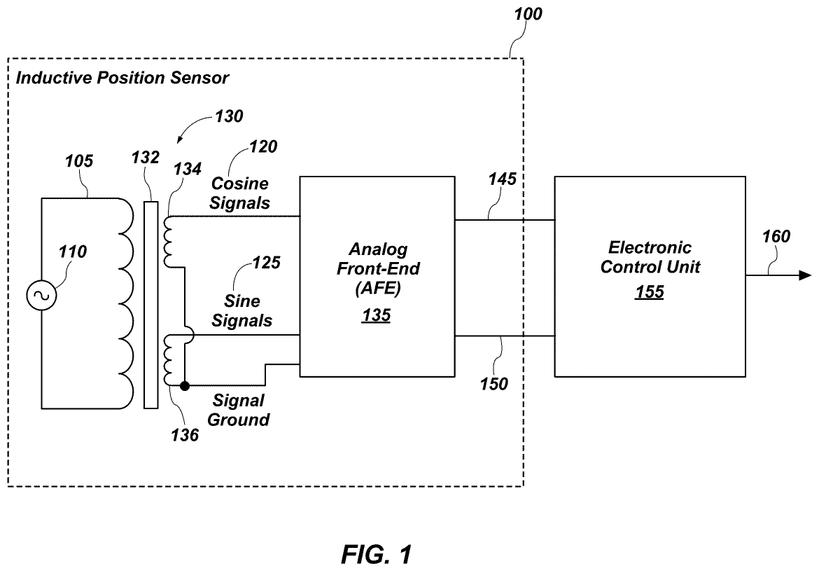

FIG. 1 is a schematic diagram of an inductive position sensor 100, according to one or more examples of the disclosure.

In the example of FIG. 1, inductive position sensor 100 includes inductive position sensor coils 130 (“sensor coils 130”) and a target 132. Sensor coils 130 include one or more oscillator coils 105, a first sense coil 134, and a second sense coil 136. One or more oscillator coils 105 may be referred to as one or more primary coils, and first sense coil 134 and second sense coil 136 may be referred to as secondary coils. First sense coil 134 and second sense coil 136 share a common signal ground. Sensor coils 130 may be disposed on, or in, a support structure (e.g., a substrate, such as a PCB) (not shown in FIG. 1). In one or more examples, one or more oscillator coils 105, first sense coil 134, and second sense coil 136 are laid out as conductive traces on or in one or more layers (e.g., planes) of a PCB. Target 132 is generally positioned adjacent oscillator coil 105 and first and second sense coils 134 and 136.

In operation of inductive position sensor 100, an oscillator 110 drives one or more oscillator coils 105 to generate a time-varying magnetic field (e.g., 5 MHz, without limitation). The magnetic fields couple onto first and second sense coils 134 and 136 to produce first and second sense signals, respectively. The first and second sense signals may take the form of first and second sinusoidal signals, respectively. In one or more examples, first sense coil 134 and second sense coil 136 may be arranged to produce sinusoidal signals that are phase-shifted by 90 degrees, for example, cosine signals 120 and sine signals 125. Accordingly, raw sensor signals of inductive position sensor 100 include cosine signals 120 and sine signals 125 as indicated in FIG. 1.

Inductive position sensor 100 may also include electronic circuitry (e.g., signal processing circuitry) for inductive position sensing of a position (e.g., linear or rotational position) of target 132. In one or more examples, target 132 is made of a conductive material, such as a non-magnetic conductive metal or metal alloy (e.g., copper, aluminum, and so on), or alternatively, a magnetic conductive metal or metal alloy (e.g., carbon steel or ferritic stainless steel), without limitation. The time-varying magnetic field generated from one or more oscillator coils 105 is disturbed, according to the linear or rotational position of target 132, inducing eddy currents in target 132. Accordingly, changes in the linear or rotational position of target 132 modulate cosine signals 120 and sine signals 125.

In one or more examples, the electronic circuitry of inductive position sensor 100 includes an analog front-end (AFE) 135. AFE 135 is to receive cosine signals 120 and sine signals 125. In one or more examples, AFE 135 is to filter, demodulate, and amplify cosine signals 120 and sine signals 125 to produce analog differential signals. In one or more examples, AFE 135 includes output pins 145 and 150 to output the analog differential signals (i.e., the filtered, demodulated, and amplified signals). In one or more examples, the electronic circuitry is to further calculate a linear or angular position of target 132 based on cosine signals 120 and sine signals 125. In one or more examples, the electronic circuitry includes a processor to perform such calculations. In one or more examples, the linear or angular position of target 132 may be calculated based on an arctangent of the ratio of cosine signals 120 and sine signals 125. In one or more examples, outputs of the position circuitry include a calculated position (e.g., linear or angular position) of target 132.

In one or more examples, output pins 145 and 150 of AFE 135 are operably coupled to an electronic control unit 155. The analog differential signals at output pins 145 and 150 may be monitored by electronic control unit 155. In one or more examples, electronic control unit 155 is to calculate the linear or angular position of target 132 based on the analog differential signals. Here, the calculated linear or angular position of target 132 may be provided at an output 160 of electronic control unit 155.

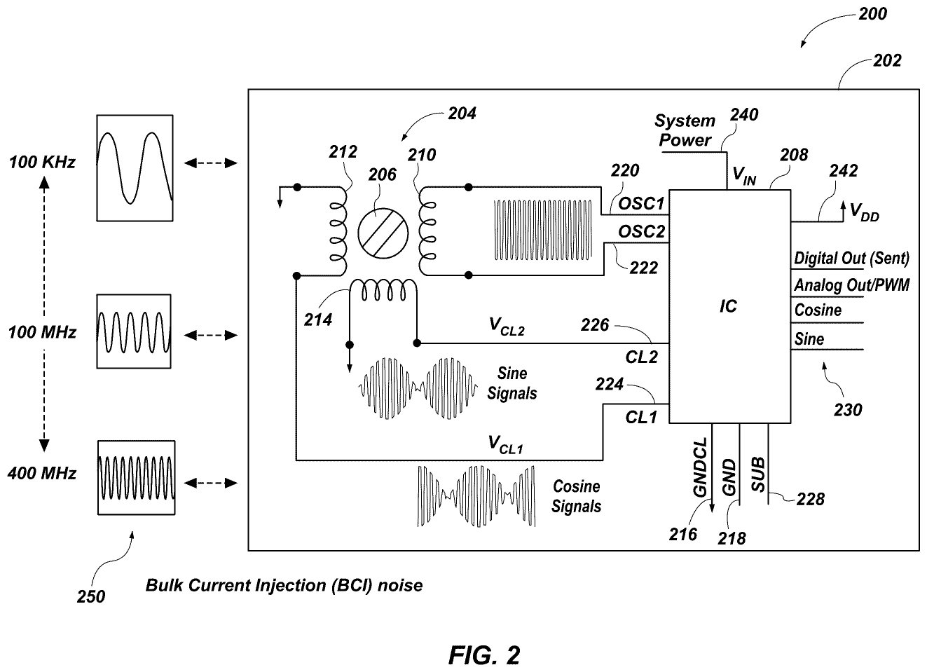

FIG. 2 is a schematic diagram of an inductive position sensor 200, according to one or more examples. In one or more examples, inductive position sensor 200 is a more specific example of inductive position sensor 100 of FIG. 1, and may be configured to operate in the same or similar manner as described in relation to FIG. 1.

In general, inductive position sensor 200 includes inductive position sensor coils 204 (“sensor coils 204”) and a target 206. Sensor coils 204 include one or more oscillator coils 210, a first sense coil 212, and a second sense coil 214. Sensor coils 204 may be disposed on or in a support structure (e.g., a substrate, such as a PCB 202). One or more oscillator coils 210, first sense coil 212, and second sense coil 214 may be laid out as conductive traces on or in one or more layers (e.g., planes) of PCB 202. Target 206 is generally positioned adjacent one or more oscillator coils 210 and first and second sense coils 212 and 214.

Inductive position sensor 200 also includes an IC 208 having electronic circuitry (e.g., AFE 135 of FIG. 1) to perform signal processing for detection of a position (e.g., linear or rotational) of target 206. As depicted in FIG. 2, IC 208 includes various input and output (I/O) pins, including a power supply input 240 (V_{IN}) and a ground input 218 (GND) to receive power from a power source (e.g., a battery or car battery). IC 208 also includes a regulator voltage output 242 (V_{DD}) from an internal voltage regulator, which provides power to the electronic circuitry of IC 208.

IC 208 also includes I/O pins for coupling sensor coils 204 to the electronic circuitry of IC 208. More particularly, the I/O pins of IC 208 include a first oscillator output 220 (OSC1) and a second oscillator output 222. First oscillator output 220 (OSC1) is coupled to a first end of one or more oscillator coils 210, and second oscillator output 222 (OSC2) is coupled to a second end of one or more oscillator coils 210. First oscillator output 220 (OSC1) and second oscillator output 222 (OSC2) are to provide oscillator signals to drive one or more oscillator coils 210 to produce a time-varying magnetic field. The I/O pins of IC 208 further include a first signal input 224 (CL1), a second signal input 226 (CL2), and a signal ground input 216 (GNDCL). First sense coil 212 has a first end coupled to first signal input 224 (CL1) and a second end coupled to signal ground input 216 (GNDCL). Second sense coil 214 has a first end coupled to second signal input 226 (CL2) and a second end coupled to signal ground input 216 (GNDCL). First signal input 224 (CL1) and signal ground input 216 (GNDCL) are to receive a first (coil) signal from first sense coil 212 (induced from the time-varying magnetic field), and a second signal input 226 (CL2) and signal ground input 216 (GNDCL) are to receive a second (coil) signal from second sense coil 214 (also induced from the time-varying magnetic field). Additional output pins 230 of IC 208 include cosine and sine signal outputs, an analog signal output, and a digital signal output.

The electronic circuitry of IC 208 is disposed on a substrate or IC substrate (not shown in FIG. 2) of IC 208. The substrate of IC 208 is or includes a baseboard (e.g., a physical platform) that connects IC 208 to PCB 202. A substrate ground input 228 (SUB) of IC 208 is coupled to a substrate ground of the substrate. The substrate ground is at least part of, or coupled to, the substrate (e.g., the substrate ground and the substrate may refer to the same common reference). In one or more examples, signal ground input 216 is coupled to ground input 218 on PCB 202.

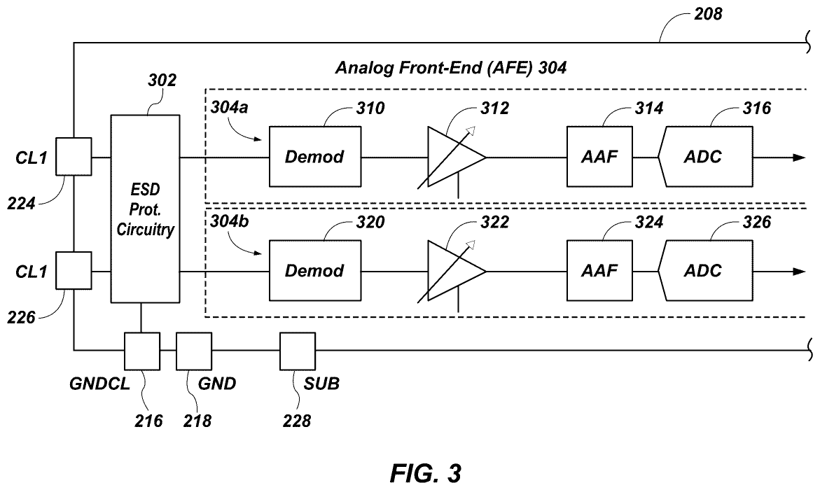

FIG. 3 is a schematic diagram of electronic circuitry of IC 208 of FIG. 2, according to one or more examples.

As shown, the electronic circuitry of IC 208 includes an ESD protection circuitry 302 and an AFE 304. ESD protection circuitry 302 may be alternatively referred to as an ESD circuit, an ESD structure or structures, an ESD protection structure, a filter circuit, an electromagnetic interference (EMI) filter, or EMI components, as but a few examples. ESD protection circuitry 302 is coupled to first signal input 224 (CL1), second signal input 226 (CL2), and signal ground input 216 (GNDCL). AFE 304 is also coupled to first signal input 224 (CL1), second signal input 226 (CL2), and signal ground input 216 (GNDCL) (e.g., following ESD protection circuitry 302).

In one or more examples, AFE 304 includes a first AFE circuitry 304a and a second AFE circuitry 304b. First AFE circuitry 304a is coupled to first signal input 224 (CL1) and signal ground input 216 (GNDCL). Second AFE circuitry 304b is coupled to second signal input 226 (CL2) and signal ground input 216 (GNDCL). In one or more examples, first AFE circuitry 304a includes a demodulator 310, a variable amplifier 312, an anti-aliasing filter (AAF) 314, an analog-to-digital converter (ADC) 316, and/or other processing circuitry. Likewise, second AFE circuitry 304b includes a demodulator 320, a variable amplifier 322, an AAF 324, an ADC 326, and/or other processing circuitry.

With reference to both FIGS. 2 and 3, during operation of inductive position sensor 200, an excitation circuitry is to generate an excitation signal in one or more oscillator coils 210 to produce a time-varying magnetic field. The time-varying magnetic field is to induce a first sense signal in first sense coil 212 and a second sense signal in second sense coil 214. The first and the second sense signals are modulated according to the changing position of target 206. First analog front-end circuitry 304a of AFE 304 is to receive, from first sense coil 212, the first (modulated) sense signal between first signal input 224 (CL1) and signal ground input 216 (GNDCL) and process the first (modulated) sense signal. Second analog front-end circuitry 304b of AFE 304 is to receive, from second sense coil 214, the second (modulated) sense signal between second signal input 226 (CL2) and signal ground input 216 (GNDCL) and process the second (modulated) sense signal. A linear or angular position of the target may be calculated based on the filtered, demodulated, and/or amplified signals from first AFE circuitry 304a and second AFE circuitry 304b.

In general, ESD protection circuitry 302 of FIG. 3 provides a low impedance path for electrostatic discharge during ESD events in order to protect the electronic circuitry of IC 208 (e.g., AFE 304). However, the electronic circuitry of IC 208 still remains subject to substantial external noise through the input pins of IC 208, which may interfere with measurements of the target position.

In automotive applications, for example, it is known that a vehicle contains a wiring harness as a source of noise. A wiring harness typically includes an organized set of wires, terminals and connectors that run throughout a vehicle and relay information and electric power to and from different vehicle components. In such an environment, high frequency currents are injected into power lines and traverse through the PCB lines to the input pins of IC 208. As a result of the external noise, position signal measurements of the inductive position sensor may be adversely affected.

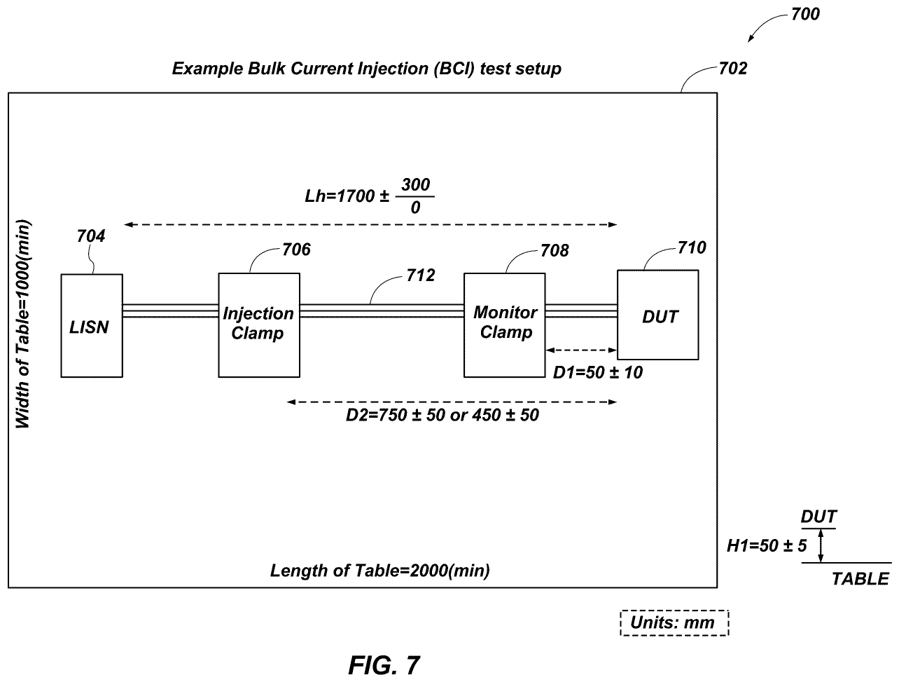

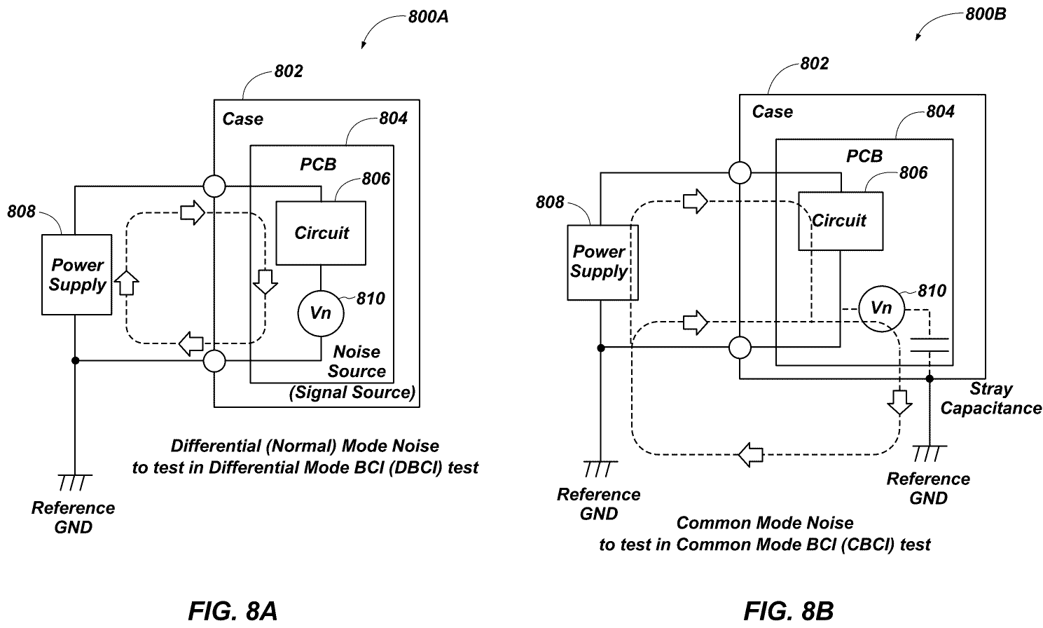

To assure proper operation in this environment, inductive position sensor 200 may be made compliant with International Organization for Standardization (ISO) 11452. ISO 11452 specifies harness excitation test methods and procedures for determining the immunity of electronic components of passenger cars and commercial vehicles. Specifically, ISO 11452-4 specifies bulk current injection (BCI) test methods based on current injection into the wiring harness using a current probe as a transformer, where the wiring harness forms the secondary winding. To ensure that inductive position sensor 200 is compliant with ISO 11452-4, BCI testing may be performed on inductive position sensor 200 using a BCI test setup. In one or more examples, the BCI test setup may be the example BCI test setup shown and described later in relation to FIGS. 7, 8A, and 8B.

During BCI testing, current signals 250 (FIG. 2) at high frequencies are injected into the power lines and traverse through conductive traces of PCB 202 to the input pins of IC 208. Current signals 250 may have high frequencies spanning over the range of 100 kHz to 400 MHz. The input pins of IC 208 receive a BCI modulated signal, which is the input signal (e.g., first and second modulated sense signals) plus the BCI injected noise signal. As sensor coils 204 are formed as conductive traces on or in the PCB 202, stray PCB resonances may be triggered, which result in high voltage amplitudes at the input pins. The high voltage amplitudes will encounter the initial structures at the input pins, namely, diodes of ESD protection circuitry 302. Due to the high voltage amplitudes, diodes of ESD protection circuitry 302 become forward biased and undesirably clip the input signals, and therefore information may be lost.

A PCB having coil windings laid out as conductive traces on, or in, the PCB (a “PCB sensor design”) resonates at certain high frequencies due to a parasitic inductance/capacitance (LC) of the PCB. Thus, a PCB sensor design has an inherent nature that tends to exhibit multiple resonances such that signal distortion is more prevalent at certain frequencies. Given the PCB resonances, the modulated input signals at the input pins of IC 208 tend to have a very high amplitude. In three-dimensional (3D) simulations for BCI injection, it has been observed that the resonance voltages may reach up to ten (10) volts peak-to-peak. Even with filtering, the resonance voltages may reach above one (1) volt, which is greater than the voltage drop of a diode.

Further complications arise if the IC is adapted to support “ground off” protection (e.g., “GND OFF” protection). A switch used for ground off protection provides an inherent series resistance connection between the ground input and the substrate or substrate ground. In the previously-known ESD structure, all of the diodes of the ESD structure reference the substrate ground, and an impedance mismatch exists between the substrate ground and the sense coil ground. When the signal clipping activity caused by the BCI injection distorts the substrate ground, due to a finite power supply rejection ratio (PSRR), the substrate ground disturbance propagates through the analog signal chain and adversely affects the desired information.

Thus, high frequency noise signals interact with signals from the first and the second sense coils to generate amplitude modulated signals around certain resonant frequencies of the PCB. Voltages as high as ten's (10's) of volts may appear due to these resonances. Even if the IC includes filtering in the signal path, the input signals initially encounter diodes of the ESD structure at the pin level. At each input pin, a diode is connected to the substrate ground, and the return path of ESD current is through the substrate of the IC. As the substrate is connected to the ground via a ground off detection switch, noise due to BCI injection may be led into the system due to an impedance mismatch between the substrate ground and the sense coil ground. Eventually, BCI error gets added into the calculation of the position of the target.

Accordingly, a BCI impact reduction topology for inductive position sensors is desired, especially a BCI impact reduction topology for PCB sensor designs.

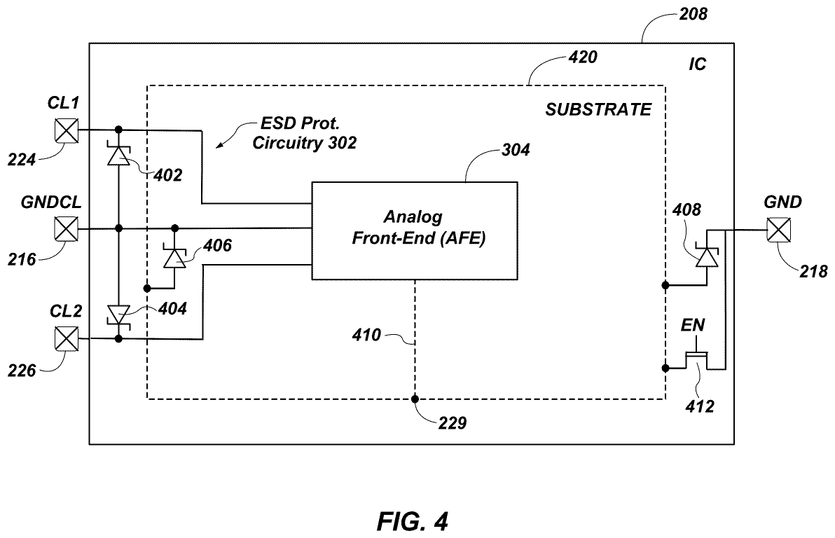

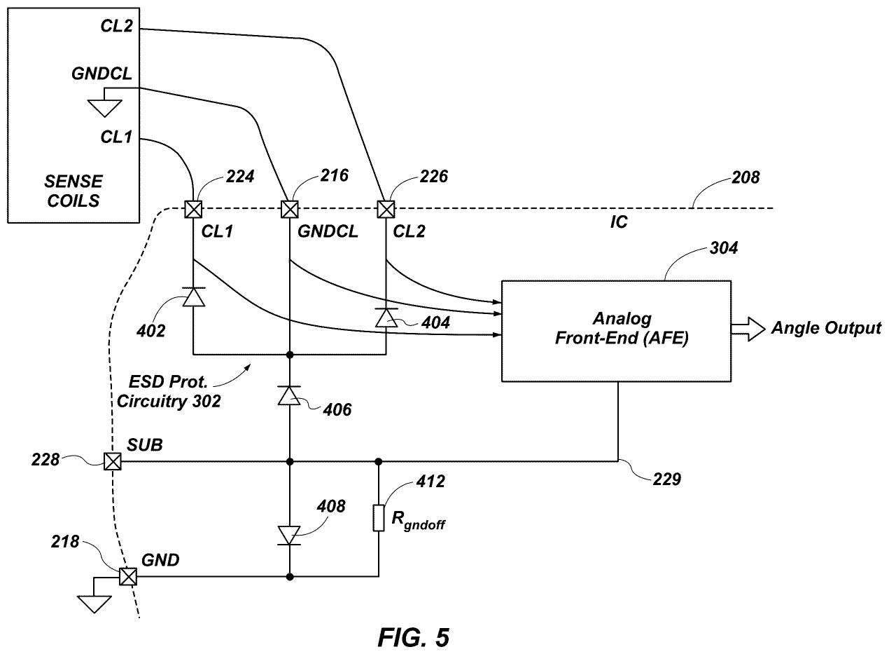

FIG. 4 is a schematic diagram of IC 208 including ESD protection circuitry 302, according to one or more examples of the disclosure. FIG. 5 is another schematic diagram of IC 208 including ESD protection circuitry 302 of FIG. 4, according to one or more examples.

As shown in FIGS. 4 and 5, ESD protection circuitry 302 includes a diode 402 having a cathode coupled to first signal input 224 and an anode coupled to signal ground input 216, a diode 404 having a cathode coupled to second signal input 226 and an anode coupled to signal ground input 216, and a diode 406 having a cathode coupled to signal ground input 216 and an anode coupled to a substrate ground 229 of a substrate 420 (or IC substrate).

Substrate ground 229 may be at least part of, or coupled to, substrate 420 (e.g., substrate ground 229 and substrate 420 may refer to the same common reference). As described earlier, substrate 420 is or includes a baseboard (e.g., a physical platform) that connects IC 208 to the PCB. The electronic circuitry of IC 208, including at least a portion of ESD protection circuitry 302 (e.g., diode 406) and AFE 304, are disposed on substrate 420 of IC 208. In addition, the electronic circuitry of IC 208, including AFE 304, is grounded to substrate ground 229 (e.g., via a substrate ground connection 410). Substrate ground input 228 (FIG. 5) is also coupled to substrate ground 229 of substrate 420. In one or more examples, ESD protection circuitry 302 further includes a diode 408 having a cathode coupled to ground input 218 and an anode coupled to substrate ground 229 of substrate 420.

In one or more examples, IC 208 is adapted to support a ground off protection function for protecting IC 208 from an adverse effect of a ground disconnection of the power source. For this purpose, a switch 412 is coupled between ground input 218 and substrate ground 229, and therefore ground input 218 has a connection to substrate ground 229 through switch 412 (i.e., via an inherent switch resistance R_{gndoff}). Switch 412 is to switchably break the connection between ground input 218 and substrate ground 229 at least partially responsive to disconnection of a ground of the power source (e.g., triggered and/or identified via an enable signal (“EN”) in FIG. 4). In a specific, non-limiting example, switch 412 is an N-type metal-oxide-semiconductor (NMOS) switch, without limitation.

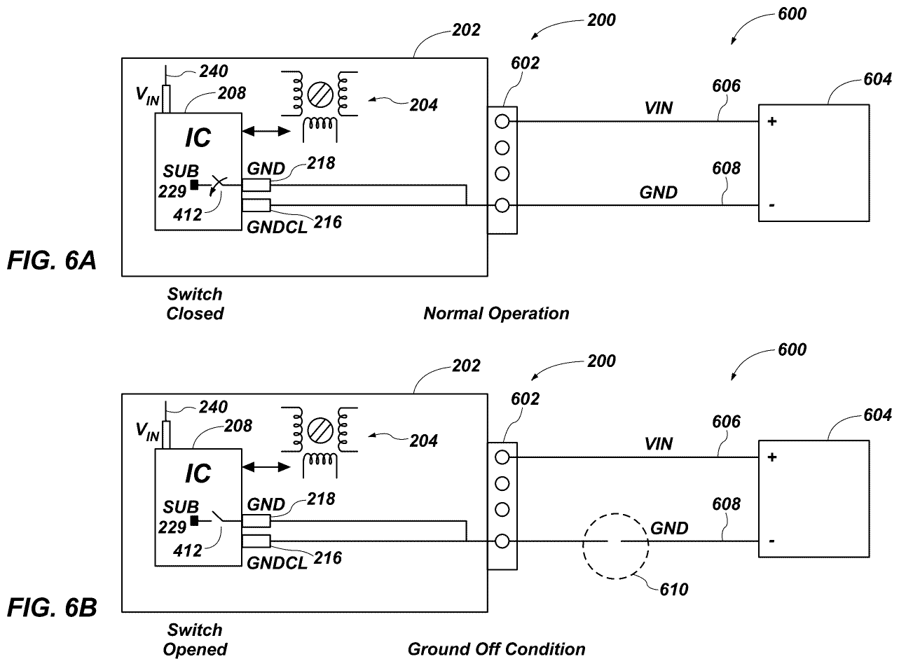

To better illustrate, FIG. 6A is a schematic diagram of a system 600 including inductive position sensor 200 and a power source 604 for supply power to inductive position sensor 200, according to one or more examples. Power source 604 may include one or more batteries (e.g., a vehicle battery). In FIG. 6A, inductive position sensor 200 includes a connector 602 to connect inductive position sensor 200 to power source 604 via wired connections (e.g., wires or cables). For example, inductive position sensor 200 may be connected to power source 604 via a wired connection 606 to a positive terminal (+) of the battery and a wired connection 608 to a negative terminal (−) of the battery. Connector 602 is mechanically and electrically connected to PCB 202. IC 208 is to receive power from power source 604 between power supply input 212 and ground input 218. In normal operation, a ground of power source 604 is coupled to ground input 218. Ground input 218 has a connection to substrate ground 229 through switch 412, which remains closed during the normal operation of system 600 as illustrated in FIG. 6A.

FIG. 6B is a schematic diagram of system 600 of FIG. 6A in a ground off condition, according to one or more examples. In the ground off condition, a disconnection 610 between the ground of power source 604 and ground input 218 occurs (e.g., wired connection 608 to the negative terminal (−) of the battery is broken). In response to detection of the ground off condition, switch 412 is to switchably break the connection between ground input 218 and substrate ground 229 in IC 208.

In one or more examples, the ESD protection circuitry of the disclosure serves as a BCI impact reduction topology for an inductive position sensor to reduce the impact of injected noise while maintaining ESD performance. It is desirable that an inductive position sensor operates effectively in high interference environments and/or is ISO-11452-4 test compliant. As described previously, ISO 11452-4 specifies BCI test methods to validate such compliance.

FIG. 7 is a depiction of a BCI test setup 700 for testing a device under test (DUT) 710, which may be an inductive position sensor, according to one or more examples (e.g., inductive position sensor 200 of FIGS. 2, 3, 4, and 5). In BCI test setup 700, DUT 710 is connected to a first end of a wire harness 712 having a length Lahr. A monitor clamp 708 for signal monitoring is positioned to wire harness 712 at a distance D1 from DUT 710. An injection clamp 706 for current injection is positioned to wire harness 712 at a distance D2 from DUT 710. A line impedance stabilization network (LISN) 704 is coupled to a second end of wire harness 712. For BCI testing, wire harness 712, LISN 704, injection clamp 706, monitor clamp 708, and DUT 710 are laid out on a test table 702. BCI testing may include differential mode BCI (DBCI) testing, common mode BCI (CBCI) testing, or both DBCI and CBCI testing.

FIG. 8A is a circuit diagram 800A to represent differential (normal) mode noise to be measured in DBCI testing. In FIG. 8A, a case 802 includes a PCB 804 having a circuit 806. Circuit 806 is connected to a power supply 808 via power supply lines to receive power. A noise source 810 (Vn) representing differential mode noise is shown coupled to circuit 806. As indicated in FIG. 8A, a noise current flows on the same path as the power supply current, and the noise voltage occurs across the power supply lines.

FIG. 8B is a circuit diagram 800B to represent common mode noise to be measured in CBCI testing. In FIG. 8B, noise source 810 (Vn) representing common mode noise is shown coupled to circuit 806 and a reference ground via a stray capacitance. As indicated in FIG. 8B, noise voltage is not present across the power supply lines, but rather across the power supply line and the reference ground. Noise currents flow in the same direction on the positive and negative sides of power supply 808.

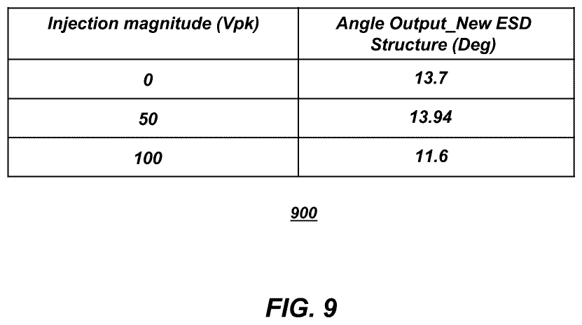

Example simulation results and measurements of BCI testing are illustrated in FIGS. 9, 10, 11, and 12 for an inductive position sensor or IC including the ESD protection circuitry, according to one or more examples (e.g., inductive position sensor 200 of FIGS. 2, 3, 4, and 5).

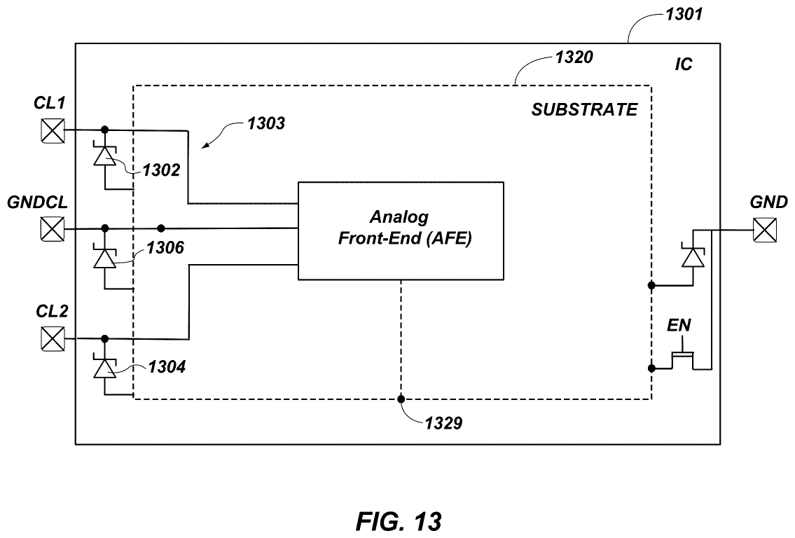

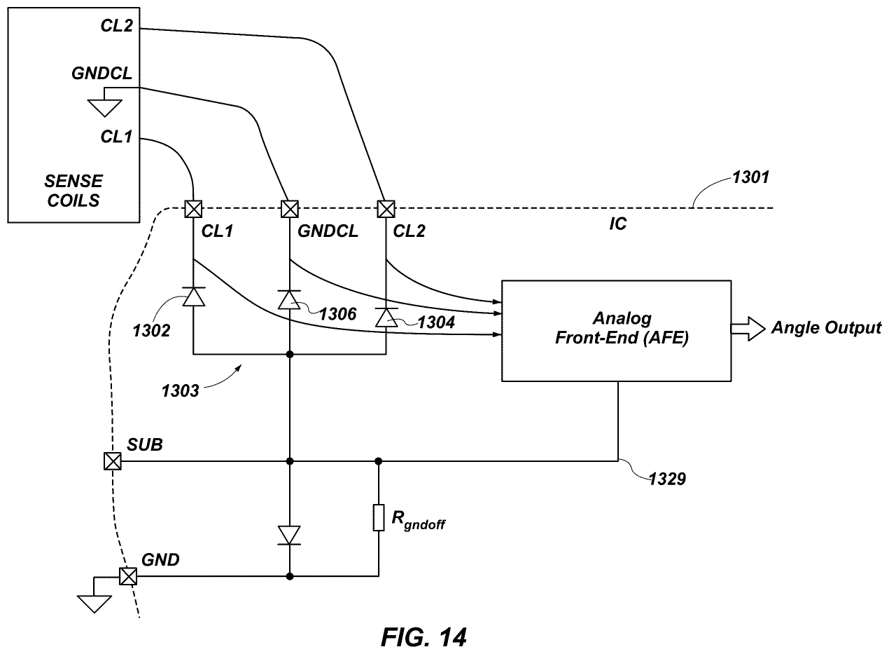

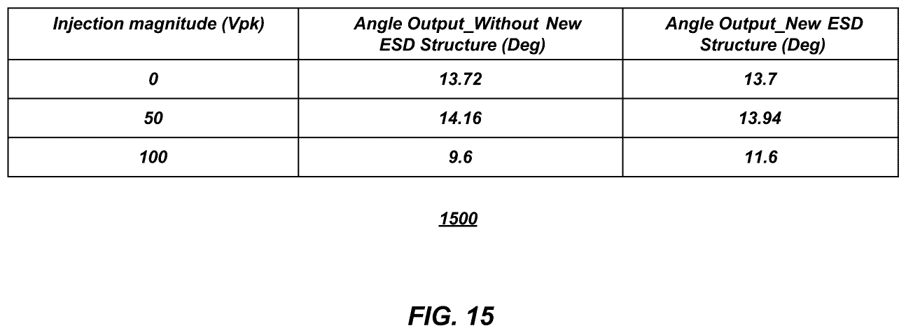

FIG. 9 is a table 900 depicting angle outputs versus injection voltage magnitudes (peak-to-peak) for an inductive position sensor or IC including an ESD protection circuitry, according to one or more examples. The angle outputs in table 900 of FIG. 9 (indicated in degrees) may be compared with angle outputs in a table 1500 of FIG. 15 for the inductive position sensor or IC without the new ESD protection circuitry (e.g., FIGS. 13 and 14).

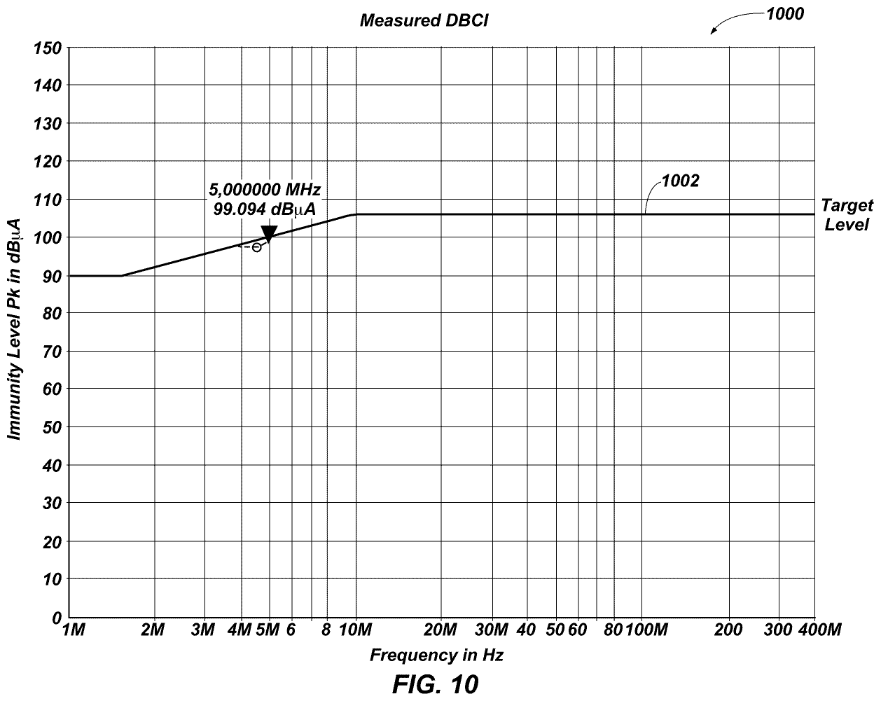

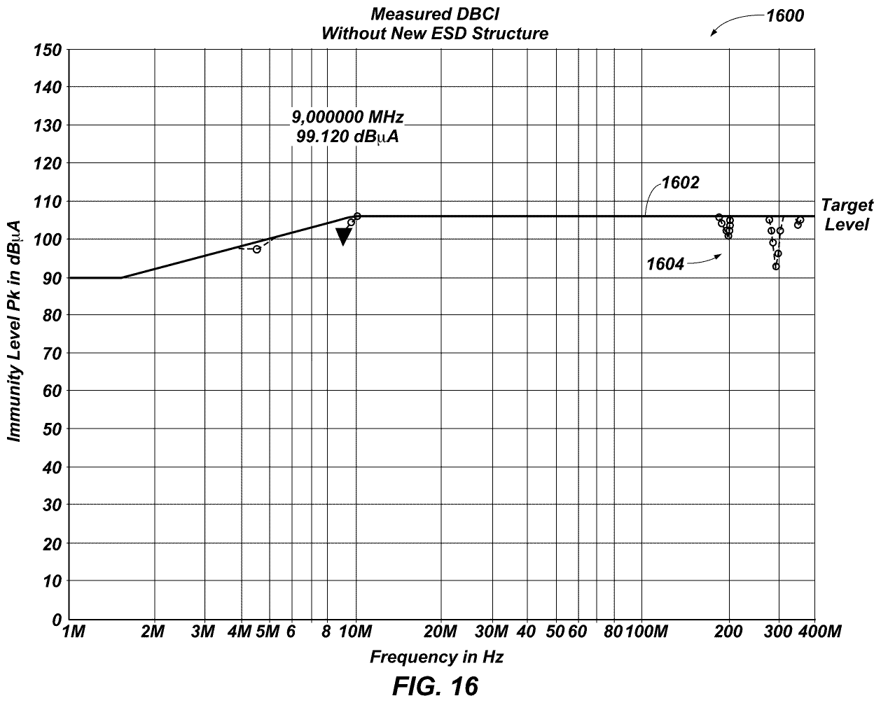

FIG. 10 is a graph 1000 depicting noise immunity level versus frequency for measured DBCI of an inductive position sensor or IC including an ESD protection circuitry, according to one or more examples. As indicated in graph 1000, an immunity level curve 1002 for the inductive position sensor or IC is in agreement with an indicated target level. Immunity level curve 1002 of FIG. 10 may be compared with an immunity level curve 1602 of FIG. 16 for the inductive position sensor or IC without the new ESD protection circuitry (e.g., FIGS. 13 and 14).

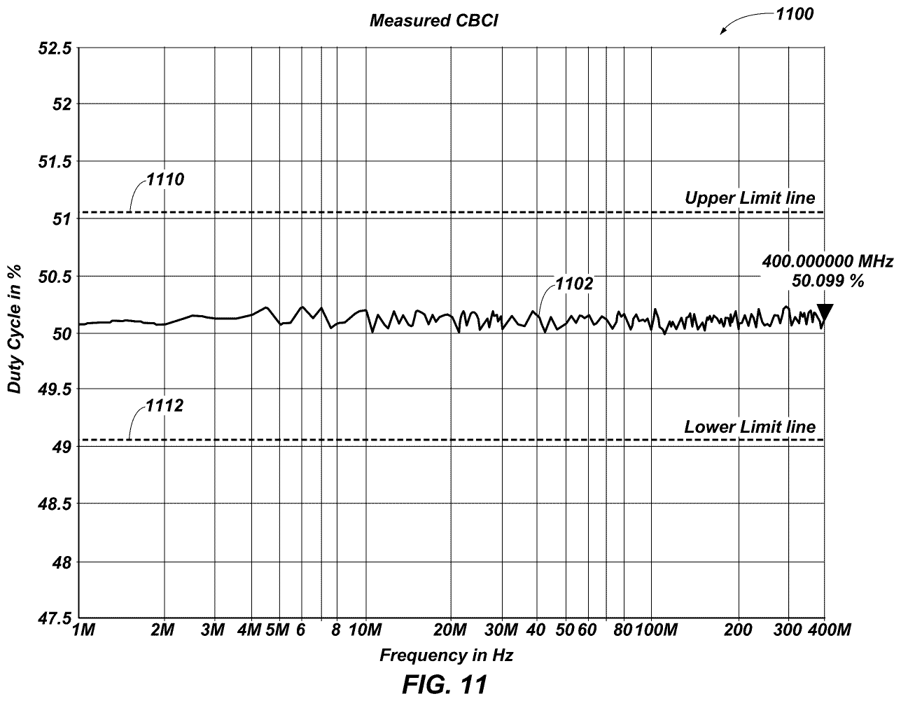

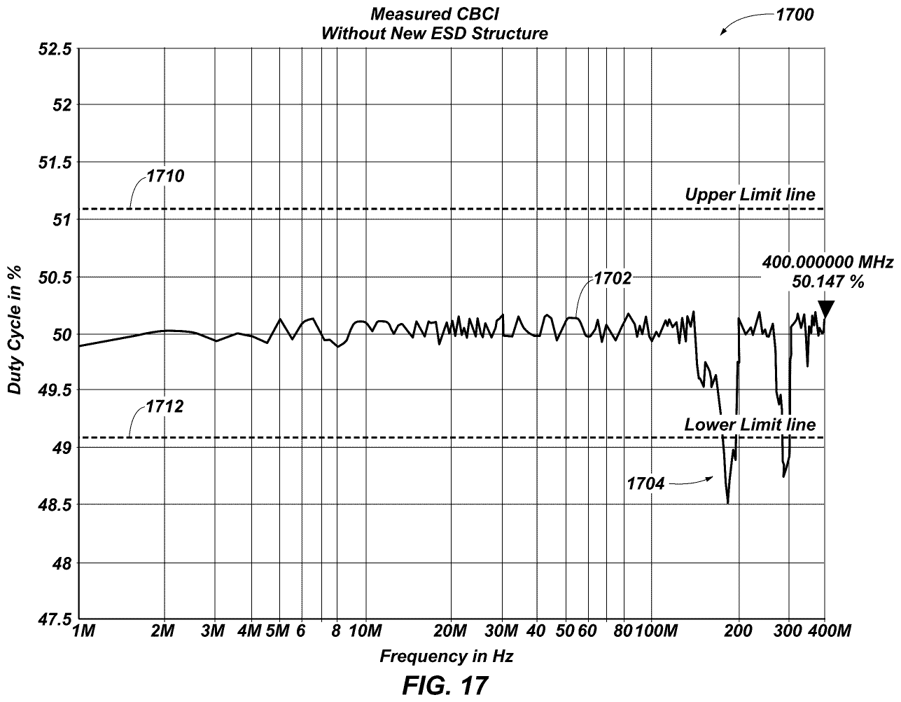

FIG. 11 is a graph 1100 depicting duty cycle versus frequency for measured CBCI of an inductive position sensor or IC including an ESD protection circuitry, according to one or more examples. As indicated in graph 1100, a duty cycle curve 1102 for the inductive position sensor or IC remains within an upper limit threshold 1110 and a lower limit threshold 1112. Duty cycle curve 1102 of FIG. 11 may be compared with a duty cycle curve 1702 of FIG. 17 for the inductive position sensor or IC without the new ESD protection circuitry (e.g., FIGS. 13 and 14).

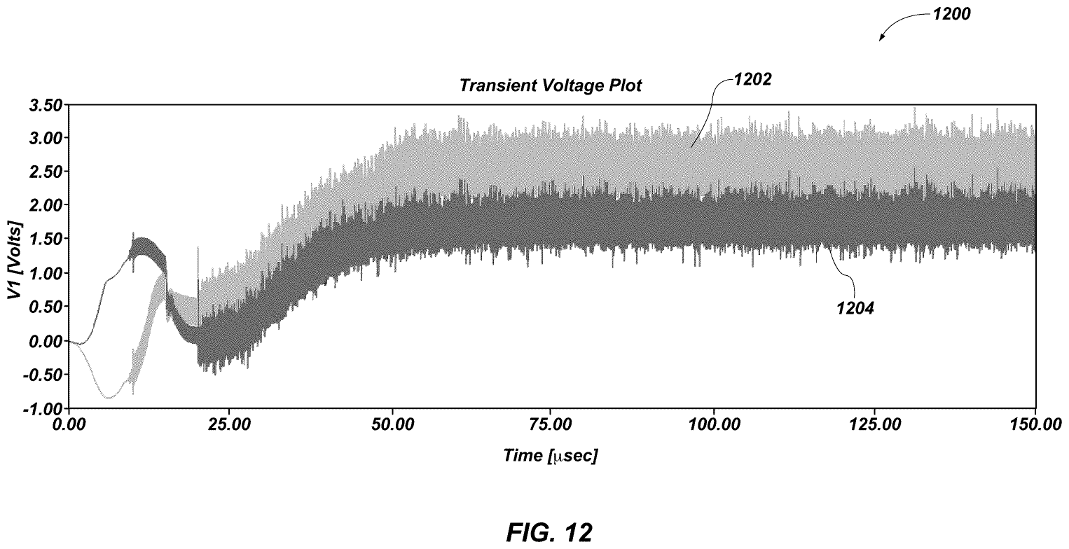

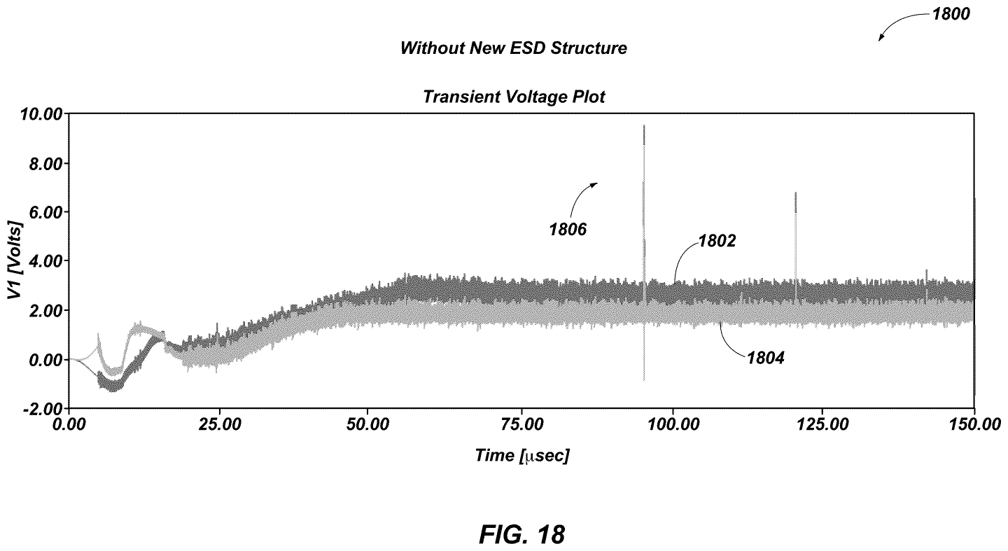

FIG. 12 is a graph 1200 of transient voltage over time for depicting ground off sensitivity for an inductive position sensor or IC including an ESD protection circuitry, according to one or more examples. In graph 1200, a first curve 1202 is associated with a first filtering (e.g., for a first signal) and a second curve 1204 is associated with a second filtering (e.g., for a second signal). In one or more examples, the ESD protection circuitry is to remove the sensitivity of ground off detection circuitry with respect to BCI. The transient voltage of FIG. 12 may be compared with the transient voltage of FIG. 18 for the inductive position sensor or IC without the new ESD protection circuitry (e.g., FIGS. 13 and 14).

Advantageously, the ESD protection circuitry, according to one or more examples, reduces the impact of BCI injected noise without negatively affecting ESD performance. In general, the example simulation results and measurements of FIGS. 9, 10, 11, and 12 may be compared with example simulation results and measurements of FIGS. 15, 16, 17, and 18 associated with an inductive position sensor or IC including an ESD protection circuitry of FIGS. 13 and 14.

FIG. 13 is a schematic diagram of an IC 1301 including an ESD protection circuitry 1303 that is known to the inventors of the disclosure. FIG. 14 is another schematic diagram of IC 1301 including ESD protection circuitry 1303 of FIG. 13. In ESD protection circuitry 1303, diodes 1302, 1304, and 1306 are coupled between the input pins (i.e., CL1, CL2, and GNDCL) and a substrate ground 1329 of a substrate 1320 of IC 1301. Given very high signal amplitudes at the input pins, signal clipping occurs at diodes 1302, 1304, and 1306. In some instances, angle output information of the inductive position sensor is altered or even completely lost.

FIG. 15 is table 1500 for depicting angle outputs versus injection voltage magnitudes (peak-to-peak) for the inductive position sensor or IC including an ESD protection circuitry, according to one or more examples, which includes angle outputs for the inductive position sensor or IC without the new ESD protection circuitry (e.g., FIGS. 13 and 14). As indicated in FIG. 15, the angle outputs for the inductive position sensor or IC of the disclosure are more accurate than those of the previous sensor or IC without the new ESD protection circuitry. In one or more examples, the variation in angle output for the ESD structure of the disclosure is within a predetermined acceptable tolerance level.

FIG. 16 is a graph 1600 depicting noise immunity level versus frequency for measured DBCI of an inductive position sensor or IC without the new ESD protection circuitry. As indicated in graph 1600, an immunity level curve 1602 for the inductive position sensor or IC is outside of an indicated target level, at a signal curve portion 1604, at higher frequencies. Immunity level curve 1602 of FIG. 16 may be compared with immunity level curve 1002 of FIG. 10 for the inductive position sensor or IC including an ESD protection circuitry, according to one or more examples.

FIG. 17 is a graph 1700 depicting duty cycle versus frequency for measured CBCI of an inductive position sensor or IC without the new ESD protection circuitry. As indicated in graph 1700, a duty cycle curve 1702 for the inductive position sensor or IC is within an upper limit threshold 1710, but is outside of a lower limit threshold 1712, at a signal curve portion 1704, at higher frequencies. Duty cycle curve 1702 of FIG. 17 may be compared with duty cycle curve 1102 of FIG. 11 for the inductive position sensor or IC including an ESD protection circuitry, according to one or more examples.

FIG. 18 is a graph 1800 of transient voltage over time for depicting ground off sensitivity for an inductive position sensor or IC without the new ESD protection circuitry. In graph 1800, a first curve 1802 is associated with a first filtering (e.g., for a first signal) and a second curve 1804 is associated with a second filtering (e.g., for a second signal). High transient voltages are indicated at signal curve portions 1806. The transient voltage of FIG. 18 may be compared with the transient voltage of FIG. 12 for the inductive position sensor or IC including an ESD protection circuitry, according to one or more examples.

Accordingly, in one or more examples, the ESD protection circuitry of the disclosure reduces the impact of BCI injected noise while maintaining ESD performance. In one or more examples, an inductive position sensor or IC including the ESD protection circuitry of the disclosure maintains position sensor accuracy even in high interference environments. In one or more examples, the variation in angle output for a sensor including the ESD structure of the disclosure is established within a predetermined acceptable tolerance level.

In one or more examples, the ESD structure of the disclosure is arranged between the inputs of the IC for both ESD protection and noise isolation. In one or more specific examples, the diodes of the ESD structure are arranged strategically between the input pins of the IC with reference to a common node. In one or more examples, the ESD structure is arranged so that signal clipping will occur at a higher voltage. In one or more examples, the ESD structure avoids excessive signal clipping to provide a clean signal to the IC for post-processing and proper extraction of useful signal information. In one or more examples, a clean ground (i.e., the ground of the PCB sensor) is provided for the ESD structure. In one or more examples, the ESD structure is arranged so as to not disturb the internal reference ground as the BCI noise clamps at the input pins with respect to the clean ground. In one or more examples, the ESD structure is arranged to improve the ground PSRR of the AFE with respect to the ground of the ESD structure.

In one or more examples, an inductive position sensor or IC including the ESD protection circuitry is suitable for use in automotive applications, as well as other applications, without limitation. In one or more examples, an inductive position sensor or IC including the ESD protection circuitry is configured to be ISO-11452-4 test compliant. In one or more examples, the ESD structure is arranged to ensure that adverse effects of DBCI and/or CBCI are reduced. In one or more examples, the ESD structure is arranged to considerably reduce BCI noise for both DBCI and CBCI.

In one or more examples, the IC is adapted to support ground off detection functionality while maintaining effective sensor operation even in high interference environments. In one or more examples, the ESD structure maintains a solid ground as a ground reference for the input pins of the IC. In one or more examples, the ESD structure is provided with a cleaner ground reference used for other parts of the IC without interfering with performance. In one or more examples, the ESD structure is arranged to remove the sensitivity of ground off detection with respect to BCI.

In addition, the term “substantially” in reference to a given parameter, property, or condition means and includes to a degree that one skilled in the art would understand that the given parameter, property, or condition is met with a small degree of variance, such as within acceptable manufacturing tolerances. For example, a parameter that is substantially met may be at least about 90% met, at least about 95% met, or even at least about 99% met.

Further, the terms “module” or “component” may refer to specific hardware implementations to perform the actions of the module or component and/or software objects or software routines that may be stored on and/or executed by general purpose hardware (e.g., computer-readable media, processing devices, etc.) of the computing system. In some examples, the different components, modules, engines, and services described in the present disclosure may be implemented as objects or processes that execute on the computing system (e.g., as separate threads). While some of the system and methods described in the present disclosure are generally described as being implemented in software (stored on and/or executed by general purpose hardware), specific hardware implementations or a combination of software and specific hardware implementations are also possible and contemplated.

As used in the present disclosure, the term “combination” with reference to a plurality of elements may include a combination of all the elements or any of various different subcombinations of some of the elements. For example, the phrase “A, B, C, D, or combinations thereof” may refer to any one of A, B, C, or D; the combination of each of A, B, C, and D; and any subcombination of A, B, C, or D such as A, B, and C; A, B, and D; A, C, and D; B, C, and D; A and B; A and C; A and D; B and C; B and D; or C and D.

Terms used in the present disclosure and especially in the appended claims (e.g., bodies of the appended claims) are generally intended as “open” terms (e.g., the term “including” should be interpreted as “including, but not limited to,” the term “having” should be interpreted as “having at least,” the term “includes” should be interpreted as “includes, but is not limited to,” etc.).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to examples containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations.

In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.,” or “one or more of A, B, and C, etc.,” is used, in general such a construction is intended to include A alone, B alone, C alone, A and B together, A and C together, B and C together, or A, B, and C together, etc.

Any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

Additional non-limiting examples of the disclosure include:

Example 1: An apparatus comprising: an electrostatic discharge (ESD) protection circuitry including: a first diode having a cathode coupled to a first signal input and an anode coupled to a signal ground input; a second diode having a cathode coupled to a second signal input and an anode coupled to the signal ground input; and a third diode having a cathode coupled to the signal ground input and an anode coupled to a substrate ground.

Example 2: The apparatus according to Example 1, comprising: a substrate, the substrate ground at least part of, or coupled to, the substrate.

Example 3: The apparatus according to Examples 1 and 2, comprising: an analog front-end, the analog front-end disposed on the substrate, the analog front-end including: a first analog front-end circuitry coupled to the first signal input and the signal ground input; and a second analog front-end circuitry coupled to the second signal input and the signal ground input.

Example 4: The apparatus according to Examples 1 to 3, comprising: an integrated circuit (IC) including the substrate, the ESD protection circuitry, and the analog front-end.

Example 5: The apparatus according to Examples 1 to 4, wherein the IC includes a power supply input and a ground input, the ground input having a connection in the IC to the substrate ground.

Example 6: The apparatus according to Examples 1 to 5, wherein the ESD protection circuitry includes: a fourth diode having a cathode coupled to the ground input and an anode coupled to the substrate ground.

Example 7: The apparatus according to Examples 1 to 6, wherein the IC is to receive power between the power supply input and the ground input from a power source, the apparatus comprising: a switch coupled between the ground input and the substrate ground, the switch to switchably break the connection at least partially responsive to a disconnection of a ground of the power source.

Example 8: The apparatus according to Examples 1 to 7, comprising: a support structure; and inductive position sensor coils on, or in, the support structure, the inductive position sensor coils including: one or more oscillator coils; a first sense coil having a first end and a second end, the first end coupled to the first signal input and the second end coupled to the signal ground input; and a second sense coil having a first end and a second end, the first end coupled to the second signal input and the second end coupled to the signal ground input.

Example 9: The apparatus according to Examples 1 to 8, wherein the support structure comprises a printed circuit board (PCB), and the inductive position sensor coils comprise conductive traces on one or more layers of the PCB.

Example 10: An apparatus comprising: an integrated circuit (IC) comprising: an electrostatic discharge (ESD) protection circuitry including: a first diode having a cathode coupled to a first signal input of the IC and an anode coupled to a signal ground input of the IC; a second diode having a cathode coupled to a second signal input of the IC and an anode coupled to the signal ground input; and a third diode having a cathode coupled to the signal ground input and an anode coupled to a substrate ground of the IC; and an analog front-end including a first analog front-end circuitry and a second analog front-end circuitry, the first analog front-end circuitry coupled to the first signal input and the signal ground input, the second analog front-end circuitry coupled to the second signal input and the signal ground input.

Example 11: The apparatus according to Example 10, wherein the IC comprises: a substrate, the substrate ground at least part of, or coupled to, the substrate, the analog front-end disposed on the substrate.

Example 12: The apparatus according to Examples 10 and 11, wherein the IC includes a power supply input and a ground input, the ground input having a connection in the IC to the substrate ground.

Example 13: The apparatus according to Examples 10 to 12, wherein the ESD protection circuitry includes: a fourth diode having a cathode coupled to the ground input and an anode coupled to the substrate ground.

Example 14: The apparatus according to Examples 10 to 13, wherein the IC is to receive power between the power supply input and the ground input from a power source, the IC comprising: a switch coupled between the ground input and the substrate ground, the switch to switchably break the connection at least partially responsive to a disconnection of a ground of the power source.

Example 15: The apparatus according to Examples 10 to 14, comprising: a support structure; inductive position sensor coils on, or in, the support structure, the inductive position sensor coils including: one or more oscillator coils; a first sense coil having a first end and a second end, the first end coupled to the first signal input and the second end coupled to the signal ground input; and a second sense coil having a first end and a second end, the first end coupled to the second signal input and the second end coupled to the signal ground input.

Example 16: The apparatus according to Examples 10 to 15, wherein the support structure comprises a printed circuit board (PCB), and the inductive position sensor coils comprise conductive traces on one or more layers of the PCB.

Example 17: The apparatus according to Examples 10 to 16, wherein: the IC comprises an excitation circuitry to generate an excitation signal in the one or more oscillator coils to produce a time-varying magnetic field, the time-varying magnetic field to induce a first sense signal in the first sense coil and a second sense signal in the second sense coil, the first analog front-end circuitry is to receive, from the first sense coil, the first sense signal between the first signal input and the signal ground input, and the second analog front-end circuitry is to receive, from the second sense coil, the second sense signal between the second signal input and the signal ground input.

Example 18: An apparatus comprising: a support structure; an integrated circuit (IC) on the support structure, the IC comprising: an electrostatic discharge (ESD) protection circuitry including: a first diode having a cathode coupled to a first signal input of the IC and an anode coupled to a signal ground input of the IC; a second diode having a cathode coupled to a second signal input of the IC and an anode coupled to the signal ground input; and a third diode having a cathode coupled to the signal ground input and an anode coupled to a substrate ground of the IC; and an analog front-end including a first analog front-end circuitry and a second analog front-end circuitry, the first analog front-end circuitry coupled to the first signal input and the signal ground input, the second analog front-end circuitry coupled to the second signal input and the signal ground input; inductive position sensor coils on, or in, the support structure, the inductive position sensor coils including: one or more oscillator coils; a first sense coil having a first end and a second end, the first end coupled to the first signal input and the second end coupled to the signal ground input; and a second sense coil having a first end and a second end, the first end coupled to the second signal input and the second end coupled to the signal ground input.

Example 19: The apparatus according to Example 18, the IC comprising: a substrate, the substrate ground at least part of, or coupled to, the substrate, the analog front-end disposed on the substrate.

Example 20: The apparatus according to Examples 18 and 19, wherein the support structure comprises a printed circuit board (PCB), and the inductive position sensor coils comprise conductive traces on one or more layers of the PCB.

Example 21: The apparatus according to Examples 18 to 20, wherein the IC includes a power supply input and a ground input, the ground input having a connection in the IC to the substrate ground.

Example 22: The apparatus according to Examples 18 to 21, wherein the ESD protection circuitry comprises: a fourth diode having a cathode coupled to the ground input and an anode coupled to the substrate ground.

Example 23: The apparatus according to Examples 18 to 22, wherein the IC is to receive power between the power supply input and the ground input from a power source, the IC comprising: a switch coupled between the ground input and the substrate ground, the switch to switchably break the connection at least partially responsive to a disconnection of a ground of the power source.

Example 24: The apparatus according to Examples 18 to 23, wherein the IC comprises: an excitation circuitry to generate an excitation signal in the one or more oscillator coils to produce a time-varying magnetic field, the time-varying magnetic field to induce a first sense signal in the first sense coil and a second sense signal in the second sense coil.

Example 25: The apparatus according to Examples 18 to 24, wherein: the first analog front-end circuitry is to receive, from the first sense coil, the first sense signal between the first signal input and the signal ground input; and the second analog front-end circuitry is to receive, from the second sense coil, the second sense signal between the second signal input and the signal ground input.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the invention as hereinafter claimed along with their legal equivalents. In addition, features from one example may be combined with features of another example while still being encompassed within the scope of the invention as contemplated by the inventor.

What is claimed is:

1. An apparatus comprising:
an electrostatic discharge (ESD) protection circuitry including:
a first diode having a cathode coupled to a first signal input and an anode coupled to a signal ground input;
a second diode having a cathode coupled to a second signal input and an anode coupled to the signal ground input; and
a third diode having a cathode coupled to the signal ground input and an anode coupled to a substrate ground.

2. The apparatus of claim 1, comprising:
a substrate, the substrate ground at least part of, or coupled to, the substrate.

3. The apparatus of claim 2, comprising:
an analog front-end, the analog front-end disposed on the substrate, the analog front-end including:
a first analog front-end circuitry coupled to the first signal input and the signal ground input; and
a second analog front-end circuitry coupled to the second signal input and the signal ground input.

4. The apparatus of claim 3, comprising:
an integrated circuit (IC) including the substrate, the ESD protection circuitry, and the analog front-end.

5. The apparatus of claim 4, wherein the IC includes a power supply input and a ground input, the ground input having a connection in the IC to the substrate ground.

6. The apparatus of claim 5, wherein the ESD protection circuitry includes:
a fourth diode having a cathode coupled to the ground input and an anode coupled to the substrate ground.

7. The apparatus of claim 6, wherein the IC is to receive power between the power supply input and the ground input from a power source, the apparatus comprising:
a switch coupled between the ground input and the substrate ground, the switch to switchably break the connection at least partially responsive to a disconnection of a ground of the power source.

8. The apparatus of claim 3, comprising:
a support structure; and
inductive position sensor coils on, or in, the support structure, the inductive position sensor coils including:
one or more oscillator coils;
a first sense coil having a first end and a second end, the first end coupled to the first signal input and the second end coupled to the signal ground input; and
a second sense coil having a first end and a second end, the first end coupled to the second signal input and the second end coupled to the signal ground input.

9. The apparatus of claim 8, wherein the support structure comprises a printed circuit board (PCB), and the inductive position sensor coils comprise conductive traces on one or more layers of the PCB.

10. An apparatus comprising:
an integrated circuit (IC) comprising:
an electrostatic discharge (ESD) protection circuitry including:
a first diode having a cathode coupled to a first signal input of the IC and an anode coupled to a signal ground input of the IC;
a second diode having a cathode coupled to a second signal input of the IC and an anode coupled to the signal ground input; and
a third diode having a cathode coupled to the signal ground input and an anode coupled to a substrate ground of the IC; and
an analog front-end including a first analog front-end circuitry and a second analog front-end circuitry, the first analog front-end circuitry coupled to the first signal input and the signal ground input, the second analog front-end circuitry coupled to the second signal input and the signal ground input.

11. The apparatus of claim 10, wherein the IC comprises:
a substrate, the substrate ground at least part of, or coupled to, the substrate, the analog front-end disposed on the substrate.

12. The apparatus of claim 10, wherein the IC includes a power supply input and a ground input, the ground input having a connection in the IC to the substrate ground.

13. The apparatus of claim 12, wherein the ESD protection circuitry includes:
a fourth diode having a cathode coupled to the ground input and an anode coupled to the substrate ground.

14. The apparatus of claim 13, wherein the IC is to receive power between the power supply input and the ground input from a power source, the IC comprising:
a switch coupled between the ground input and the substrate ground, the switch to switchably break the connection at least partially responsive to a disconnection of a ground of the power source.

15. The apparatus of claim 10, comprising:
a support structure;
inductive position sensor coils on, or in, the support structure, the inductive position sensor coils including:
one or more oscillator coils;
a first sense coil having a first end and a second end, the first end coupled to the first signal input and the second end coupled to the signal ground input; and
a second sense coil having a first end and a second end, the first end coupled to the second signal input and the second end coupled to the signal ground input.

16. The apparatus of claim 15, wherein the support structure comprises a printed circuit board (PCB), and the inductive position sensor coils comprise conductive traces on one or more layers of the PCB.

17. The apparatus of claim 16, wherein:
the IC comprises an excitation circuitry to generate an excitation signal in the one or more oscillator coils to produce a time-varying magnetic field, the time-varying magnetic field to induce a first sense signal in the first sense coil and a second sense signal in the second sense coil,
the first analog front-end circuitry is to receive, from the first sense coil, the first sense signal between the first signal input and the signal ground input, and
the second analog front-end circuitry is to receive, from the second sense coil, the second sense signal between the second signal input and the signal ground input.

18. An apparatus comprising:
a support structure;
an integrated circuit (IC) on the support structure, the IC comprising:
an electrostatic discharge (ESD) protection circuitry including:
a first diode having a cathode coupled to a first signal input of the IC and an anode coupled to a signal ground input of the IC;
a second diode having a cathode coupled to a second signal input of the IC and an anode coupled to the signal ground input; and
a third diode having a cathode coupled to the signal ground input and an anode coupled to a substrate ground of the IC; and
an analog front-end including a first analog front-end circuitry and a second analog front-end circuitry, the first analog front-end circuitry coupled to the first signal input and the signal ground input, the second analog front-end circuitry coupled to the second signal input and the signal ground input;
inductive position sensor coils on, or in, the support structure, the inductive position sensor coils including:
one or more oscillator coils;
a first sense coil having a first end and a second end, the first end coupled to the first signal input and the second end coupled to the signal ground input; and
a second sense coil having a first end and a second end, the first end coupled to the second signal input and the second end coupled to the signal ground input.

19. The apparatus of claim 18, the IC comprising:
a substrate, the substrate ground at least part of, or coupled to, the substrate, the analog front-end disposed on the substrate.

20. The apparatus of claim 19, wherein the support structure comprises a printed circuit board (PCB), and the inductive position sensor coils comprise conductive traces on one or more layers of the PCB.

21. The apparatus of claim 20, wherein the IC includes a power supply input and a ground input, the ground input having a connection in the IC to the substrate ground.

22. The apparatus of claim 21, wherein the ESD protection circuitry comprises:
a fourth diode having a cathode coupled to the ground input and an anode coupled to the substrate ground.

23. The apparatus of claim 22, wherein the IC is to receive power between the power supply input and the ground input from a power source, the IC comprising:
a switch coupled between the ground input and the substrate ground, the switch to switchably break the connection at least partially responsive to a disconnection of a ground of the power source.

24. The apparatus of claim 20, wherein the IC comprises:
an excitation circuitry to generate an excitation signal in the one or more oscillator coils to produce a time-varying magnetic field, the time-varying magnetic field to induce a first sense signal in the first sense coil and a second sense signal in the second sense coil.

25. The apparatus of claim 24, wherein:
the first analog front-end circuitry is to receive, from the first sense coil, the first sense signal between the first signal input and the signal ground input; and
the second analog front-end circuitry is to receive, from the second sense coil, the second sense signal between the second signal input and the signal ground input.
